(19) United States
(12) Patent Application Publication
(10) Pub. No.: US 2025/0120142 A1
(43) Pub. Date: Apr. 10, 2025

(54) SEMICONDUCTOR DEVICE AND MANUFACTURING METHOD OF SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Jun SAITO, Nisshin-shi (JP); Shin KINOSHITA, Nisshin-shi (JP); Tomofumi NIIBAYASHI, Nisshin-shi (JP)

(21) Appl. No.: 18/798,025

(22) Filed: Aug. 8, 2024

(30) Foreign Application Priority Data
Oct. 5, 2023 (JP) 2023-173671

(51) Int. Cl. H01L 29/06; H01L 29/66; H01L 29/739; H01L 29/78

(52) U.S. Cl. CPC H10D 62/126; H10D 30/0291; H10D 30/668; H10D 62/125; H10D 12/032; H10D 12/441

(57) ABSTRACT

A semiconductor device includes a semiconductor substrate that includes a first semiconductor layer of p-type, a drift layer disposed below the first semiconductor layer, and a second semiconductor layer of n-type disposed below the drift layer. The drift layer includes a first semiconductor region of a first conductivity type, and a plurality of second semiconductor regions of a second conductivity type and a plurality of third semiconductor regions of the second conductivity type distributed in the first semiconductor region. Each of the second semiconductor regions has a shape elongated in a first direction. Each of the third semiconductor regions has a shape elongated in a second direction that is perpendicular to the first direction. The second semiconductor regions and the third semiconductor regions are alternately arranged at intervals along the first direction, and are alternately arranged at intervals along the second direction.

### CROSS REFERENCE TO RELATED APPLICATION

The present application claims the benefit of priority from Japanese Patent Application No. 2023-173671 filed on Oct. 5, 2023. The entire disclosure of the above application is incorporated herein by reference.

### TECHNICAL FIELD

The present disclosure relates to a semiconductor device and a manufacturing method of a semiconductor device.

### BACKGROUND

Conventionally, there has been known a semiconductor device that includes a superjunction layer in which n-type regions and p-type regions are arranged alternately in a horizontal direction. The superjunction layer is disposed between a source region and a well region disposed adjacent to an upper surface of a semiconductor substrate and a drain layer disposed adjacent to a lower surface of the semiconductor substrate. When the semiconductor device is turned off, depletion layers spread from pn junctions at interfaces between the n-type regions and the p-type regions to the entire superjunction layer. In the above-described semiconductor device, the superjunction layer is quickly depleted, so that a high breakdown voltage can be ensured.

### SUMMARY

A semiconductor device according to one aspect of the present disclosure includes a semiconductor substrate that includes a first semiconductor layer of p-type, a drift layer disposed below the first semiconductor layer, and a second semiconductor layer of n-type disposed below the drift layer. The drift layer includes a first semiconductor region of a first conductivity type, a plurality of second semiconductor regions of a second conductivity type, and a plurality of third semiconductor regions of the second conductivity type. The second semiconductor regions and the third semiconductor regions are distributed in the first semiconductor region. Each of the second semiconductor regions has a shape elongated in a first direction along an upper surface of the semiconductor substrate. Each of the third semiconductor regions has a shape elongated in a second direction that is along the upper surface of the semiconductor substrate and is perpendicular to the first direction. The second semiconductor regions and the third semiconductor regions are alternately arranged at intervals along the first direction, and are alternately arranged at intervals along the second direction.

A manufacturing method according to another aspect of the present disclosure is a manufacturing method of the semiconductor device according to the above aspect. The manufacturing method includes forming a resist having a plurality of first opening portions and a plurality of second opening portions on an upper surface of a semiconductor layer of a first conductivity type such that each of the first opening portions has a shape elongated in the first direction along the upper surface of the semiconductor layer, each of the second opening portions has a shape elongated in the second direction that is along the upper surface of the semiconductor layer and is perpendicular to the first direction, and the first opening portions and the second opening portions are alternately arranged at intervals along the first direction and are alternately arranged at intervals along the second direction, and forming a plurality of semiconductor regions of a second conductivity type in the semiconductor layer by ion implantation of second conductivity type impurities into the semiconductor layer through the first opening portions and the second opening portions. In the semiconductor regions, regions formed by the ion implantation through the first opening portions become the second semiconductor regions, respectively. In the semiconductor regions, regions formed by the ion implantation through the second opening portions become the third semiconductor regions, respectively. In the semiconductor layer, a region that remains after the semiconductor regions are formed becomes the first semiconductor region.

### BRIEF DESCRIPTION OF DRAWINGS

Objects, features and advantages of the present disclosure will become apparent from the following detailed description made with reference to the accompanying drawings. In the drawings:

FIG. 1 is a perspective cross-sectional view of a semiconductor device according to a first embodiment;

FIG. 2 is a cross-sectional view of the semiconductor device taken along line II-II in FIG. 1;

FIG. 3 is a cross-sectional view of the semiconductor device taken along line III-III in FIG. 1;

FIG. 4 is a diagram for explaining the expansion of depletion layers on a cross section corresponding to FIG. 3 when a semiconductor device according to a comparative example is turned off;

FIG. 5 is a diagram for explaining the expansion of depletion layers on a cross section corresponding to FIG. 3 when the semiconductor device of the first embodiment is turned off;

FIG. 6 is a diagram for explaining a process of manufacturing the semiconductor device according to the first embodiment;

FIG. 7 is a diagram for explaining a process of manufacturing the semiconductor device according to the first embodiment;

FIG. 8 is a diagram for explaining a process of manufacturing the semiconductor device according to the first embodiment;

FIG. 9 is a diagram for explaining a process of manufacturing the semiconductor device according to the first embodiment;

FIG. 10 is a diagram for explaining a process of manufacturing the semiconductor device according to the first embodiment;

FIG. 11 is a perspective cross-sectional view of a semiconductor device according to a second embodiment; and

FIG. 12 is an enlarged cross-sectional view of the semiconductor device taken along line XII-XII in FIG. 11.

### DETAILED DESCRIPTION

Next, a relevant technology is described only for understanding the following embodiments. In a semiconductor device, p-type regions in a superjunction layer is generally formed by forming a resist having opening portions on an upper surface of an n-type region and ion-implanting p-type impurities into the n-type region through the opening portions. When the resist having the opening portions is formed, first, a resist is formed over the entire upper surface of the n-type region, and then regions of the resist corresponding to the opening portions are exposed to light. Thereafter, a developer is applied to remove the resist from the exposed portions. Accordingly, the opening portions are formed. At this time, the flow of the developer applies a force to the resist in portions to remain (referred to as non-exposed portions), which may cause the resist in the non-exposed portions to deform. In particular, the non-exposed portions elongated in a direction perpendicular to the flow of the developer are easily subjected to a large force and are easily deformed. If the resist is deformed, the opening portions will not be located in intended areas and the p-type impurities cannot be implanted in desired areas. As a result, characteristics of the semiconductor device may vary.

A semiconductor device according to a first aspect of the present disclosure includes a semiconductor substrate that includes a first semiconductor layer of p-type, a drift layer disposed below the first semiconductor layer, and a second semiconductor layer of n-type disposed below the drift layer. The drift layer includes a first semiconductor region of a first conductivity type, a plurality of second semiconductor regions of a second conductivity type, and a plurality of third semiconductor regions of the second conductivity type. The second semiconductor regions and the third semiconductor regions are distributed in the first semiconductor region. Each of the second semiconductor regions has a shape elongated in a first direction along an upper surface of the semiconductor substrate. Each of the third semiconductor regions has a shape elongated in a second direction that is along the upper surface of the semiconductor substrate and is perpendicular to the first direction. The second semiconductor regions and the third semiconductor regions are alternately arranged at intervals along the first direction, and are alternately arranged at intervals along the second direction.

In the present disclosure, one of the first conductivity type and the second conductivity type means p-type, and the other means n-type. That is, when the first conductivity type is p-type, the second conductivity type is n-type, and when the first conductivity type is n-type, the second conductivity type is p-type.

When the second semiconductor regions and the third semiconductor regions are formed by ion implantation, a resist having opening portions at areas corresponding to the second semiconductor regions and the third semiconductor regions is formed on an upper surface of the drift layer, and second conductivity type impurities are ion-implanted through the opening portions. In the above-described semiconductor device, the second semiconductor regions and the third semiconductor regions are alternately arranged at intervals along the first direction, and are alternately arranged at intervals along the second direction. That is, when the second semiconductor regions and the third semiconductor regions are formed, the opening portions of the resist are formed so as to be distributed along the first direction and the second direction. Therefore, the resist having the opening portions has a shape in which portions extending in the first direction and portions extending in the second direction are connected at relatively narrow intervals. In this way, in the above-described semiconductor device, when forming the resist having the opening portions, portions of the resist extending in a specific direction are reinforced by being connected at relatively narrow intervals to portions of the resist extending in a direction perpendicular to the specific direction, so that the resist is less likely to deform due to the flow of developer during development, and the second semiconductor regions and the third semiconductor regions are formed with high precision. Therefore, the semiconductor device has stable characteristics.

A manufacturing method of a semiconductor device according to a second aspect of the present disclosure includes forming a resist having a plurality of first opening portions and a plurality of second opening portions on an upper surface of a semiconductor layer of a first conductivity type such that each of the first opening portions has a shape elongated in a first direction along the upper surface of the semiconductor layer, each of the second opening portions has a shape elongated in a second direction that is along the upper surface of the semiconductor layer and is perpendicular to the first direction, and the first opening portions and the second opening portions are alternately arranged at intervals along the first direction and are alternately arranged at intervals along the second direction, and forming a plurality of semiconductor regions of a second conductivity type in the semiconductor layer by ion implantation of second conductivity type impurities into the semiconductor layer through the first opening portions and the second opening portions. The semiconductor device includes a semiconductor substrate that includes a first semiconductor layer of p-type, a drift layer disposed below the first semiconductor layer, and a second semiconductor layer of n-type disposed below the drift layer. The drift layer includes a first semiconductor region of the first conductivity type, a plurality of second semiconductor regions of the second conductivity type, and a plurality of third semiconductor regions of the second conductivity type. The second semiconductor regions and the third semiconductor regions are distributed in the first semiconductor region. Each of the second semiconductor regions has a shape elongated in the first direction. Each of the third semiconductor regions has a shape elongated in the second direction. The second semiconductor regions and the third semiconductor regions are alternately arranged at intervals along the first direction, and are alternately arranged at intervals along the second direction. In the semiconductor regions, regions formed by the ion implantation through the first opening portions become the second semiconductor regions, respectively. In the semiconductor regions, regions formed by the ion implantation through the second opening portions become the third semiconductor regions, respectively. In the semiconductor layer, a region that remains after the semiconductor regions are formed becomes the first semiconductor region.

In the above-described manufacturing method, the resist is formed such that the first opening portions and the second opening portions are alternately arranged at intervals along both the first direction and the second direction. When forming the resist, first, the resist is formed over approximately the entire upper surface of the semiconductor layer of the first conductivity type, and then portions of the resist located in areas where the first opening portions and the second opening portions are to be formed are exposed to light. Thereafter, a developer is applied to the resist to remove the exposed portions of the resist, thereby forming the first opening portions and the second opening portions. At this time, the remaining resist has a shape in which portions extending in the first direction and portions extending in the second direction are connected at relatively narrow intervals due to the first opening portions and the second opening portions. In this way, in the above-described manufacturing method, when forming the resist having the opening portions, portions of the resist extending in a specific direction are reinforced by being connected to portions of the resist extending in a direction perpendicular to the specific direction at relatively narrow intervals, so that the resist is less likely to deform due to the flow of developer during development. Therefore, the second conductivity type impurities can be precisely ion-implanted from the upper surface of the semiconductor layer through each of the first opening portions and each of the second opening portions, and the second semiconductor regions and the third semiconductor regions can be formed in the desired areas. Therefore, the above-described manufacturing method can manufacture the semiconductor device having stable characteristics.

In the semiconductor device according to the first aspect described above, a length of the second semiconductor regions in the first direction may be greater than or equal to a distance between a center of one of the second semiconductor regions and a center of one of the third semiconductor regions that are adjacent to each other in the first direction, and a length of the third semiconductor regions in the second direction may be greater than or equal to a distance between a center of one of the second semiconductor regions and a center of one of the third semiconductor regions that are adjacent to each other in the second direction.

In such a configuration, when the semiconductor device is turned off, depletion layers extend evenly inside the first semiconductor region, the second semiconductor regions, and the third semiconductor regions. That is, the entire drift layer is depleted at approximately the same timing, and there are no regions where depletion is locally delayed, so that desired breakdown voltage performance and short-circuit resistance can be achieved.

In the semiconductor device according to the first aspect described above, the drift layer may be a first drift layer. The semiconductor substrate may further include a second drift layer disposed between the first drift layer and the second semiconductor layer. The second drift layer may include a fourth semiconductor region of the first conductivity type, and a plurality of fifth semiconductor regions of the second conductivity type and a plurality of sixth semiconductor regions of the second conductivity type distributed in the fourth semiconductor region. Each of the fifth semiconductor regions may have a shape elongated in the first direction, and each of the sixth semiconductor regions may have a shape elongated in the second direction.

The fifth semiconductor regions and the sixth semiconductor regions may be alternately arranged at intervals along the first direction, and may be alternately arranged at intervals along the second direction. When the semiconductor substrate is viewed from above, one of the second semiconductor regions and a corresponding one of the sixth semiconductor regions may intersect with each other, and one of the third semiconductor regions and a corresponding one of the fifth semiconductor regions may intersect with each other.

In such a configuration, even if a misalignment occurs between the first drift layer and the second drift layer during the manufacturing process, a contact area between upper and lower semiconductor regions of the second conductivity type (that is, between the second semiconductor regions and the sixth semiconductor regions, and between the third semiconductor regions and the fifth semiconductor regions) that are distributed in first and fourth semiconductor regions of the first conductivity type is unlikely to change. Therefore, variations in junction capacitance can be restricted and the semiconductor device can exhibit desired performance.

### First Embodiment

A semiconductor device 10 according to a first embodiment of the present disclosure will be described with reference to the drawings. The semiconductor device 10 is a vertical metal-oxide-semiconductor field-effect transistor (MOSFET), and includes a semiconductor substrate 12, electrodes, an insulating film, and the like. The semiconductor substrate 12 is made of SiC. However, the material constituting the semiconductor substrate 12 is not particularly limited, and may be other semiconductor materials such as Si or GaN. In the following, a direction parallel to an upper surface 12a of the semiconductor substrate 12 may also be referred to as an x-axis direction, a direction parallel to the upper surface 12a and perpendicular to the x-axis direction may also be referred to as a y-axis direction, and a thickness direction of the semiconductor substrate 12 may also be referred to as a z-axis direction. In the present embodiment, the x-axis direction corresponds to a first direction, the y-axis direction corresponds to a second direction.

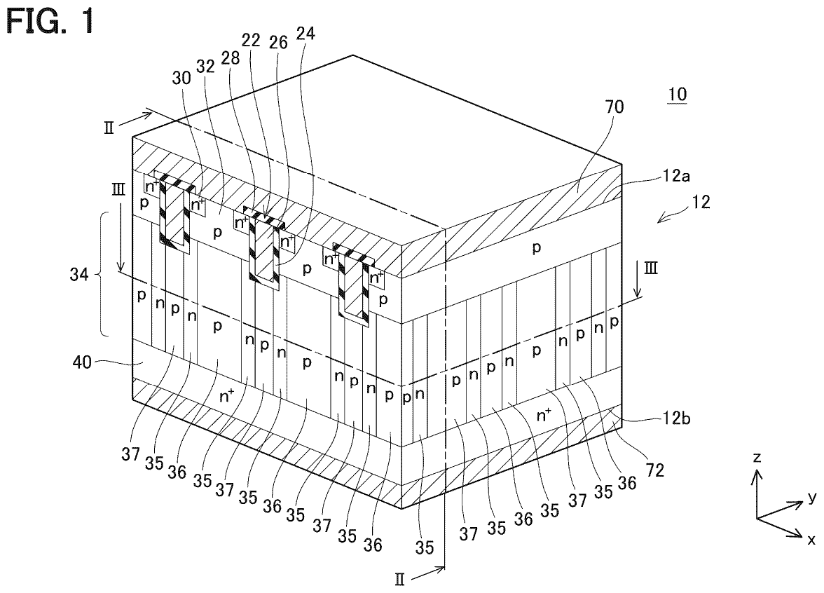

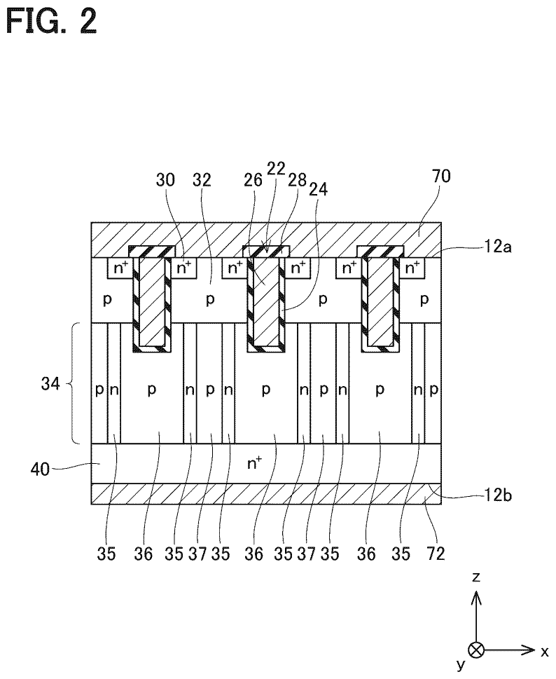

The semiconductor substrate 12 has a plurality of trenches 22 extending from the upper surface 12a. As shown in FIG. 1, the trenches 22 are arranged at intervals in the x-axis direction. Each of the trenches 22 is elongated in the y-axis direction. In each of the trenches 22, a gate insulating film 24 and a gate electrode 26 are disposed. The gate insulating film 24 covers an inner surface of each of the trenches 22. The gate electrode 26 is insulated from the semiconductor substrate 12 by the gate insulating film 24. As shown in FIG. 1 and FIG. 2, upper surfaces of the gate electrodes 26 are covered with interlayer insulating films 28. A source electrode 70 is disposed on the upper surface 12a of the semiconductor substrate 12. The source electrode 70 is in contact with the upper surface 12a of the semiconductor substrate 12 at portions where the interlayer insulating films 28 are not provided. The source electrode 70 is insulated from the gate electrodes 26 by the interlayer insulating films 28. A drain electrode 72 is disposed on a lower surface 12b of the semiconductor substrate 12. The drain electrode 72 is in contact with approximately the entire area of the lower surface 12b of the semiconductor substrate 12.

The semiconductor substrate 12 includes a plurality of source layers 30, a body layer 32, a drift layer 34, and a drain layer 40.

Each of the source layers 30 is of n-type and is exposed on the upper surface 12a of the semiconductor substrate 12. Each of the source layers 30 is in ohmic contact with the source electrode 70. Each of the source layers 30 is in contact with the gate insulating film 24 at an upper end of the trench 22.

The body layer 32 is of p-type. The body layer 32 extends from ranges sandwiched between adjacent two of the source layers 30 to below each of the source layers 30. The body layer 32 is exposed on the upper surface 12a of the semiconductor substrate 12 and is in ohmic contact with the source electrode 70. The body layer 32 is in contact with the gate insulating films 24 at positions below the source layers 30. In the present embodiment, the body layer 32 corresponds to a first semiconductor layer of p-type.

The drift layer 34 is in contact with the body layer 32 from below. The drift layer 34 includes an n-type region 35, a plurality of first p-type regions 36, and a plurality of second p-type regions 37. In the present embodiment, the n-type region 35 corresponds to a first semiconductor region of a first conductivity type, the plurality of first p-type regions 36 corresponds to a plurality of second semiconductor regions of a second conductivity type, and the plurality of second p-type regions 37 corresponds to a plurality of third semiconductor regions of the second conductivity type.

As shown in FIGS. 1 to 3, the first p-type regions 36 and the second p-type regions 37 are distributed in the n-type region 35. Each of the first p-type regions 36 and each of the second p-type regions 37 is surrounded by the n-type region 35. Each of the first p-type regions 36 and each of the second p-type regions 37 extends from an upper end to a lower end of the drift layer 34.

As shown in FIG. 1 and FIG. 2, each of the first p-type regions 36 is connected to a lower end of the body layer 32 and extends downward from the body layer 32. Therefore, a potential of each of the first p-type regions 36 is approximately equal to a potential of the source electrode 70. As shown in FIG. 1, a part of the second p-type regions 37 extends downward from lower ends of the trenches 22. That is, the part of the second p-type regions 37 is separated from the body layer 32 by the n-type region 35. Therefore, a potential of the part of the second p-type regions 37 is floating. As shown in FIG. 2, another part of the second p-type regions 37 is connected to the body layer 32 and extends downward from the body layer 32. Therefore, a potential of the another part of the second p-type regions 37 is approximately equal to the potential of the source electrode 70.

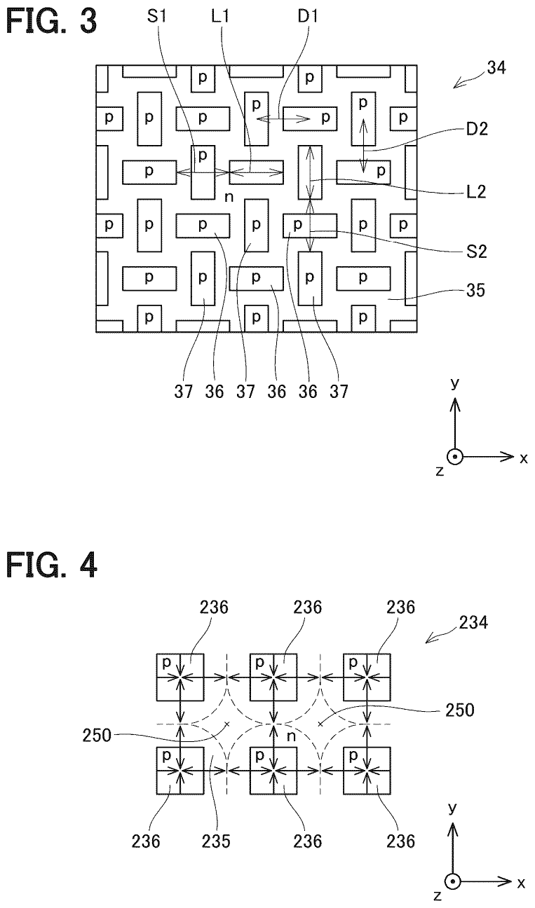

FIG. 3 is a cross-sectional view along the xy plane at a particular depth of the drift layer 34 when the semiconductor substrate 12 is viewed from above (that is, along the z-axis direction). As shown in FIG. 3, each of the first p-type regions 36 has a shape elongated in the x-axis direction. That is, each of the first p-type regions 36 has a longitudinal direction (that is, a long-side direction) in the x-axis direction and a lateral direction (that is, a short-side direction) in the y-axis direction. Each of the second p-type regions 37 has a shape elongated in the y-axis direction. That is, each of the second p-type regions 37 has a longitudinal direction in the y-axis direction and a lateral direction in the x-axis direction.

The first p-type regions 36 and the second p-type regions 37 are alternately arranged at intervals along the x-axis direction. The first p-type regions 36 and the second p-type regions 37 are alternately arranged at intervals along the y-axis direction. Each of the first p-type regions 36 and each of the second p-type regions 37 are separated by the n-type region 35.

A length L1 of the first p-type regions 36 in the longitudinal direction (the x-axis direction) and a length L2 of the second p-type regions 37 in the longitudinal direction (the y-axis direction) are approximately equal to each other. The length L1 of the first p-type regions 36 in the longitudinal direction is approximately equal to a distance D1 between a center of one of the first p-type regions 36 and a center of one of the second p-type regions 37 that are adjacent to each other in the x-axis direction. The length L2 of the second p-type region 37 in the longitudinal direction is approximately equal to a distance D2 between a center of one of the first p-type regions 36 and a center of one of the second p-type regions 37 that are adjacent to each other in the y-axis direction.

The length L1 of the first p-type regions 36 in the longitudinal direction is approximately equal to an interval S1 between two of the first p-type regions 36 that are adjacent to each other in the x-axis direction with one of the second p-type regions 37 interposed therebetween. Furthermore, the length L2 of the second p-type regions 37 in the longitudinal direction is approximately equal to an interval S2 between two of the second p-type regions 37 that are adjacent to each other in the y-axis direction with one of the first p-type regions 36 interposed therebetween.

As shown in FIG. 1 and FIG. 2, the drain layer 40 is n-type. An n-type impurity concentration of the drain layer 40 is higher than the n-type impurity concentration of the n-type region 35 of the drift layer 34. The drain layer 40 is in contact with the drift layer 34 from below. The drain layer 40 is exposed to the lower surface 12b of the semiconductor substrate 12. The drain layer 40 is in ohmic contact with the drain electrode 72. In the present embodiment, the drain layer 40 corresponds to a second semiconductor layer of n-type.

Next, the operation of the semiconductor device 10 will be described. When the semiconductor device 10 is in use, a voltage higher than a voltage applied to the source electrode 70 is applied to the drain electrode 72. When a voltage equal to or higher than a gate threshold value is applied to the gate electrode 26, a channel is formed in the body layer 32 in an area in contact with the gate insulating film 24, and the semiconductor device 10 is turned on. When the voltage applied to the gate electrode 26 is lowered to less than the gate threshold value, the channel disappears and the semiconductor device 10 is turned off.

When the semiconductor device 10 is in the off state, the potential of the drain electrode 72 is much higher than the potential of the source electrode 70. In this state, the n-type region 35 of the drift layer 34 has a potential close to the potential of the drain electrode 72. As described above, most of the first p-type regions 36 and the second p-type regions 37 of the drift layer 34 have the potential approximately equal to the potential of the source electrode 70. As a result, a high reverse voltage is applied to the pn junctions at the interfaces between the body layer 32, the first p-type regions 36, and the second p-type regions 37 and the n-type region 35. As a result, depletion layers spread laterally (in the xy plane direction) from the first p-type regions 36 and the second p-type regions 37 into the n-type region 35. Furthermore, depletion layers spread laterally from the n-type region 35 into the first p-type regions 36 and the second p-type regions 37. The depletion layers maintain the voltage applied between the drain electrode 72 and the source electrode 70.

Regarding the operation when the semiconductor device 10 is turned off, the effect of the semiconductor device 10 will be described in comparison with a semiconductor device according to a comparative example shown in FIG. 4. FIG. 4 is a cross-sectional view of the semiconductor device of the comparative example on a cross section corresponding to FIG. 3. The semiconductor device of the comparative example includes a drift layer 234. The drift layer 234 has a configuration in which a plurality of p-type regions 236 each having an approximately square shape is distributed and arranged at equal intervals in the x-axis direction and the y-axis directions in an n-type region 235. When the semiconductor device is turned off, depletion layers extend from pn junction surfaces between the n-type region 235 and the p-type regions 236 into the n-type region 235 and the p-type regions 236 at approximately the same speed. Therefore, as indicated by the arrows and dashed lines in FIG. 4, in the semiconductor device of the comparative example, at the time when the p-type regions 236 are completely depleted, non-depleted regions 250 remain in the n-type region 235. As described above, in the semiconductor device of the comparative example, since there exist the regions 250 where depletion is locally delayed inside the drift layer 234, an electric field is likely to concentrate at the regions 250, resulting in a decrease in the breakdown voltage and short-circuit resistance.

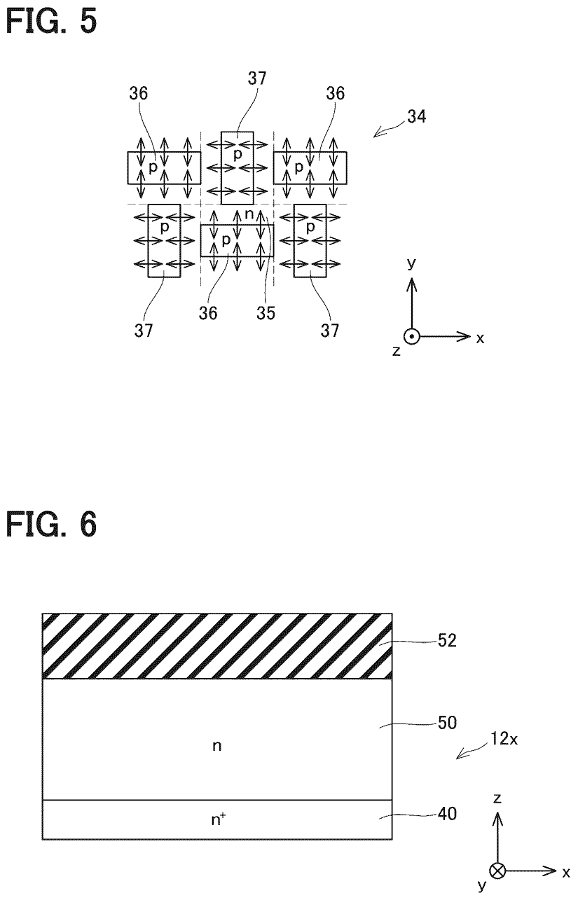

In contrast, in the present embodiment, as described above, the length L1 of the first p-type regions 36 in the longitudinal direction is approximately equal to the distance D1 between the center of one of the first p-type regions 36 and the center of one of the second p-type region 37 that are adjacent to each other in the x-axis direction. Furthermore, the length L2 of the second p-type region 37 in the longitudinal direction is approximately equal to the distance D2 between the center of one of the first p-type regions 36 and the center of one of the second p-type regions 37 that are adjacent to each other in the y-axis direction. With this configuration, as shown by arrows in FIG. 5, when the semiconductor device 10 is turned off, depletion layers extend evenly inside the n-type region 35, the first p-type regions 36, and the second p-type regions 37. That is, in the present embodiment, the entire drift layer 34 is depleted at approximately the same timing, and there are no regions where depletion is locally delayed, so that desired breakdown voltage performance and short-circuit resistance can be achieved. In FIG. 5, for ease of understanding, only the depletion layers extending from specific pn junction surfaces are shown by arrows. However, it should be noted that in reality, depletion layers similarly extend from all pn junction surfaces into the n-type region 35, the first p-type regions 36, and the second p-type regions 37.

As will be described later, in the configuration of the drift layer 34 of the present embodiment, the first p-type regions 36 and the second p-type regions 37 can be formed with high precision in desired areas. Therefore, the semiconductor device 10 of the present embodiment has stable characteristics.

Next, a manufacturing method of the semiconductor device 10 will be described with reference to FIGS. 6 to 10. FIGS. 6 to 8 and FIG. 10 show cross sections corresponding to the cross section shown in FIG. 2. The manufacturing method of the present embodiment is characterized by a process of forming the first p-type regions 36 and the second p-type regions 37. Therefore, in the following, the process of forming the first p-type regions 36 and the second p-type regions 37 will be mainly described, and a description of the other manufacturing processes will be omitted. Note that, as for the other manufacturing processes of the semiconductor device 10, necessary processes may be appropriately performed according to a structure of the semiconductor device 10.

First, as shown in FIG. 6, a semiconductor layer 12x in which an n-type semiconductor layer 50 is formed on an upper surface of the drain layer 40 of n-type is prepared. In the present embodiment, the n-type semiconductor layer 50 corresponds to a semiconductor layer of the first conductivity type. The semiconductor layer 12x can be manufactured, for example, by growing the n-type semiconductor layer 50 on the upper surface of the drain layer 40 by epitaxial growth. Next, a resist 52 is formed on approximately the entire upper surface of the n-type semiconductor layer 50.

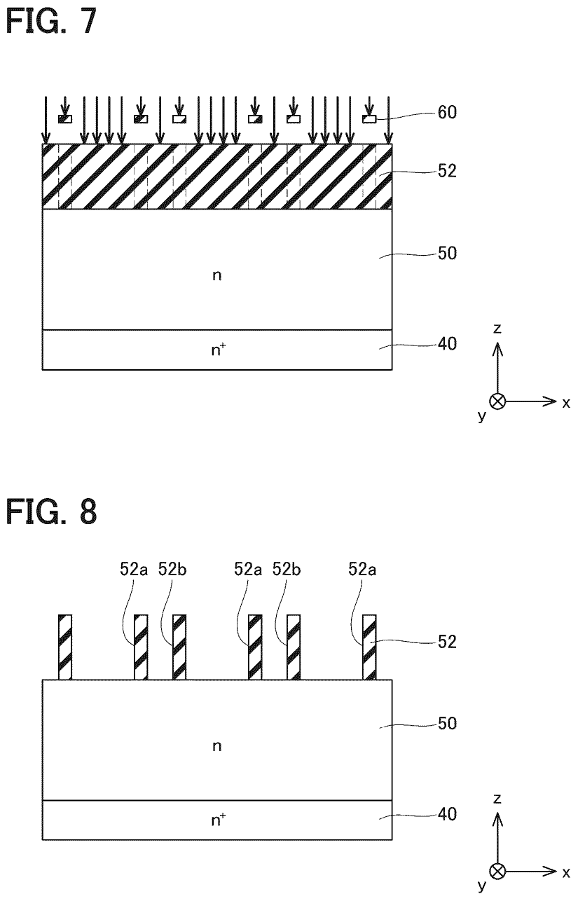

Next, as shown in FIG. 7, portions of the resist 52 located above areas where the first p-type regions 36 and the second p-type regions 37 are to be formed are exposed through a mask 60 that has opening portions above the areas where the first p-type regions 36 and the second p-type regions 37 are to be formed.

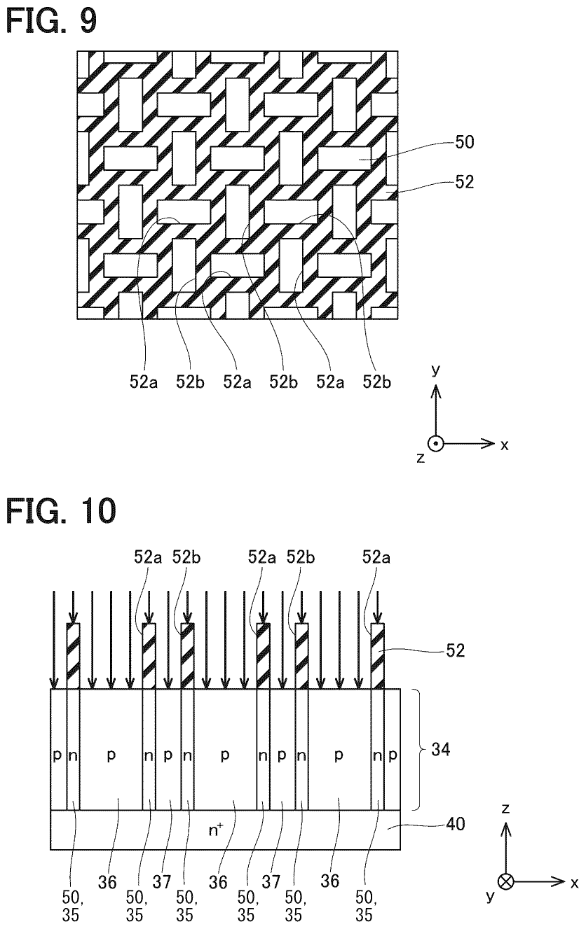

Next, a developer is applied to the upper surface of the resist 52 to remove the exposed portions of the resist 52. Specifically, the semiconductor layer 12x is placed on a developing device (not shown), and a developer is applied to the center of the resist 52 from above the resist 52. Then, the semiconductor layer 12x is rotated by the developing device. Accordingly, the developer spreads over the entire upper surface of the resist 52. As a result, as shown in FIG. 8 and FIG. 9, the exposed portions of the resist 52 are dissolved in the developer and removed, so that the resist 52 having a plurality of opening portions 52a and a plurality of opening portions 52b is formed. As shown in FIG. 9, the opening portions 52a and the opening portions 52b are formed so as to be alternately arranged at intervals along both the x-axis direction and the y-axis direction. In the present embodiment, the plurality of opening portions 52a corresponds to a plurality of first opening portions, and the plurality of opening portions 52b corresponds to a plurality of second opening portions.

Next, as shown in FIG. 10, p-type impurities (for example, aluminum) are ion-implanted from the upper surface of the n-type semiconductor layer 50 through the opening portions 52a and 52b. As a result, a plurality of p-type semiconductor regions 62 is formed. In the present embodiment, the plurality of p-type semiconductor regions 62 corresponds to a plurality of semiconductor regions of the second conductivity type. In the p-type semiconductor regions 62, regions formed by the ion implantation through the opening portions 52a become the first p-type regions 36, respectively. In the p-type semiconductor regions 62, regions formed by the ion implantation through the opening portions 52b become the second p-type regions 37, respectively. In the n-type semiconductor layer 50, a region that remains after the p-type semiconductor regions 62 are formed becomes the n-type region 35.

Thereafter, the body layer 32 and the source layers 30 are formed by a known method, and the trenches 22, the gate insulating films 24, the gate electrodes 26, the interlayer insulating films 28, the source electrode 70, and the drain electrode 72 are formed, so that the semiconductor device 10 of FIG. 1 is completed.

In the manufacturing method of the present embodiment, the resist 52 is formed such that the opening portions 52a and the opening portions 52b are alternately arranged at intervals along both the x-axis direction and the y-axis direction. That is, in the process of developing the resist 52, the remaining part of the resist 52 has a shape in which portions extending in the x-axis direction and portions extending in the y-axis direction are connected at a relatively narrow interval due to the opening portions 52a and the opening portions 52b. In this manner, in the manufacturing method of the present embodiment, when forming the resist 52 having the plurality of opening portions 52a, 52b, the resist 52 extending in a specific direction is reinforced by being connected to the resist 52 extending in a direction perpendicular to the specific direction at relatively narrow intervals, so that resist 52 is less likely to deform due to the flow of developer during development. Therefore, p-type impurities can be ion-implanted with high precision from the upper surface of the n-type semiconductor layer 50 through the opening portions 52a and the opening portions 52b, and the first p-type regions 36 and the second p-type regions 37 can be formed in the desired areas. Therefore, this manufacturing method can manufacture the semiconductor device 10 having stable characteristics.

### Second Embodiment

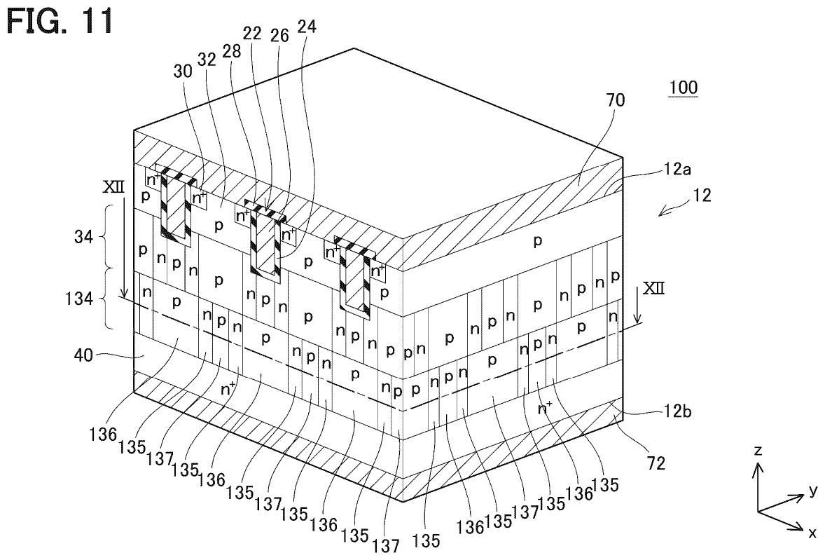

A semiconductor device 100 according to a second embodiment is different from the first embodiment in a configuration of semiconductor regions located between the body layer 32 and the drain layer 40. In the second embodiment, as shown in FIG. 11, a lower drift layer 134 is disposed between the drift layer 34 and the drain layer 40 in the first embodiment. In the present embodiment, the drift layer 34 corresponds to a first drift layer, and the lower drift layer 134 corresponds to a second drift layer.

The lower drift layer 134 is in contact with the drift layer 34 from below. The lower drift layer 134 includes an n-type region 135, a plurality of third p-type regions 136, and a plurality of fourth p-type regions 137. In the present embodiment, the n-type region 135 corresponds to a fourth semiconductor regions of the first conductivity type, the plurality of third p-type regions 136 corresponds to a plurality of fifth semiconductor regions of the second conductivity type, and the plurality of fourth p-type regions 137 corresponds to a plurality of sixth semiconductor regions of the second conductivity type.

As shown in FIG. 11, the third p-type regions 136 and the fourth p-type regions 137 are distributed in the n-type region 135. Each of the third p-type regions 136 and each of the fourth p-type regions 137 is surrounded by the n-type region 135. Each of the third p-type regions 136 and each of the fourth p-type regions 137 extends from an upper end to a lower end of the lower drift layer 134. The detailed configuration of each of the third p-type regions 136 is similar to that of each of the first p-type regions 36 of the drift layer 34, and the detailed configuration of each of the fourth p-type regions 137 is similar to that of each of the second p-type regions 37 of the drift layer 34. Therefore, description of the detailed configuration of each of the third p-type regions 136 and the detailed configuration of each of the fourth p-type regions 137 is omitted.

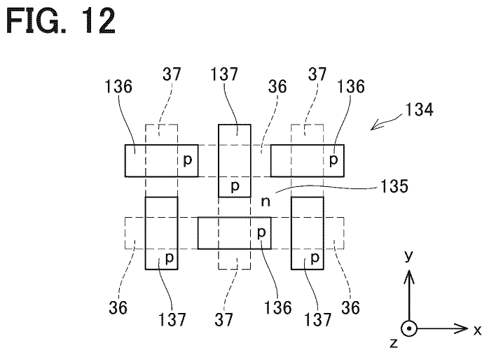

FIG. 12 is an enlarged cross-sectional view along the xy plane at a particular depth of the lower drift layer 134 when the semiconductor substrate 12 is viewed from above (along the z-axis direction). In FIG. 12, the configuration of each of the p-type regions 36 and 37 of the drift layer 34 located above the lower drift layer 134 is indicated by dashed lines. As shown in FIG. 12, in the semiconductor device 100 of the second embodiment, when the semiconductor substrate 12 is viewed from above, each of the first p-type regions 36 and a corresponding one of the fourth p-type regions 137 intersect with each other. When the semiconductor substrate 12 is viewed from above, each of the second p-type regions 37 and a corresponding one of the third p-type regions 136 intersect with each other. Each of the first p-type regions 36 is connected to the corresponding one of the fourth p-type regions 137, and each of the second p-type regions is connected to the corresponding one of the third p-type regions 136.

In the semiconductor device 100 of the second embodiment, the p-type regions of the drift layer 34 and the p-type regions of the lower drift layer 134 are arranged to intersect with each other. Therefore, even if misalignment occurs between the drift layer 34 and the lower drift layer 134 during the manufacturing process, the contact area between the upper and lower p-type regions is unlikely to change. Therefore, the semiconductor device 100 can restrict variations in junction capacitance and exhibit desired performance. Furthermore, since the thickness of each of the drift layers 34 and 134 is thinner than that of the first embodiment, the thickness of the resist can be made thinner when ion-implanting p-type impurities.

In each of the above-described embodiments, the semiconductor device may include an element region in which a MOSFET structure is formed, and a peripheral region (that is, a high breakdown voltage region) disposed around the element region. In this case, the above-described structure of the drift layer 34 may be adopted in the entire region of the element region, or the structure of the drift layer 34 may be adopted along the outer peripheral portion of the element region and a known structure may be adopted in the central portion of the element region. The outer peripheral portion of the element region is most susceptible to the force of the flow of the developer when the resist is developed. Therefore, the technique disclosed in the present disclosure is more useful when applied to the outer peripheral portion of the element region in the semiconductor device having the element region and the peripheral region.

In the first embodiment described above, the n-type region 35 of the drift layer 34 may be p-type, and the first p-type regions 36 and the second p-type regions 37 may be n-type. The same applies to the drift layer 34 and the lower drift layer 134 in the second embodiment.

In the first embodiment described above, the length L1 of the first p-type regions 36 in the longitudinal direction and the length L2 of the second p-type regions 37 in the longitudinal direction do not have to be equal to each other. Additionally, the length L1 does not have to be equal to the interval S1, and the length L2 does not have to be equal to the interval S2. Even with this configuration, the first p-type regions 36 and the second p-type regions 37 can be formed with high precision in the desired areas. It is preferable that the length L1 is equal to or greater than the interval S1, and the length L2 is equal to or greater than the interval S2. With this configuration, there are no regions in the drift layer 34 where depletion is locally delayed, so that desired breakdown voltage performance and short-circuit resistance can be achieved. The same applies to the lower drift layer 134 of the second embodiment.

In the second embodiment described above, two layers, namely, the drift layer 34 and the lower drift layer 134, are provided between the body layer 32 and the drain layer 40. However, three or more drift layers may be provided between the body layer 32 and the drain layer 40 such that the p-type regions located above and below intersect each other when viewed from above.

Furthermore, in the above-described embodiment, the MOSFET has been described as an example, but the technique disclosed in the present disclosure may also be applied to an insulated gate bipolar transistor (IGBT) or a diode, for example. In the case of an IGBT, an IGBT structure can be obtained by replacing the drain layer 40 of n-type with a p-type region. In the case of a diode, the above-described configuration of the drift layer 34 may be applied between an anode region of p-type and a cathode region of n-type.

Although the embodiments have been described in detail above, these are merely examples and do not limit the scope of claims. The techniques described in the claims include various modifications and modifications of the specific examples illustrated above. The technical elements described in the present specification or the drawings exhibit technical usefulness alone or in various combinations, and are not limited to the combinations described in the claims at the time of filing. In addition, the techniques illustrated in the present specification or drawings achieve objectives at the same time, and achieving one of the objectives itself has technical usefulness.

What is claimed is:

1. A semiconductor device comprising:
a semiconductor substrate including a first semiconductor layer of p-type, a drift layer disposed below the first semiconductor layer, and a second semiconductor layer of n-type disposed below the drift layer, wherein
the drift layer includes a first semiconductor region of a first conductivity type, a plurality of second semiconductor regions of a second conductivity type, and a plurality of third semiconductor regions of the second conductivity type,
the plurality of second semiconductor regions and the plurality of third semiconductor regions are distributed in the first semiconductor region,
each of the plurality of second semiconductor regions has a shape elongated in a first direction along an upper surface of the semiconductor substrate,
each of the plurality of third semiconductor regions has a shape elongated in a second direction that is along the upper surface of the semiconductor substrate and is perpendicular to the first direction, and
the plurality of second semiconductor regions and the plurality of third semiconductor regions are alternately arranged at intervals along the first direction, and are alternately arranged at intervals along the second direction.

2. The semiconductor device according to claim 1, wherein
a length of each of the plurality of second semiconductor regions in the first direction is equal to or greater than a distance between a center of one of the plurality of second semiconductor regions and a center of one of the plurality of third semiconductor regions that are adjacent to each other in the first direction, and
a length of each of the plurality of third semiconductor regions in the second direction is equal to or greater than a distance between a center of one of the plurality of second semiconductor regions and a center of one of the plurality of third semiconductor regions that are adjacent to each other in the second direction.

3. The semiconductor device according to claim 1, wherein
the drift layer is a first drift layer,
the semiconductor substrate further includes a second drift layer disposed between the first drift layer and the second semiconductor layer,
the second drift layer includes a fourth semiconductor region of the first conductivity type, a plurality of fifth semiconductor regions of the second conductivity type, and a plurality of sixth semiconductor regions of the second conductivity type,
the plurality of fifth semiconductor regions and the plurality of sixth semiconductor regions which are distributed in the fourth semiconductor region,
each of the fifth semiconductor region has a shape elongated in the first direction,
each of the sixth semiconductor region has a shape elongated in the second direction,
the plurality of fifth semiconductor regions and the plurality of sixth semiconductor regions are alternately arranged at intervals along the first direction, and are alternately arranged at intervals along the second direction, and
when the semiconductor substrate is viewed from above, one of the second semiconductor regions and a corresponding one of the sixth semiconductor regions intersect with each other, and one of the third semiconductor regions and a corresponding one of the fifth semiconductor regions intersect with each other.

4. A manufacturing method of a semiconductor device, comprising:
forming a resist having a plurality of first opening portions and a plurality of second opening portions on an upper surface of a semiconductor layer of a first conductivity type such that each of the plurality of first opening portions has a shape elongated in a first direction along the upper surface of the semiconductor layer, each of the plurality of second opening portions has a shape elongated in a second direction that is along the upper surface of the semiconductor layer and is perpendicular to the first direction, and the plurality of first opening portions and the plurality of second opening portions are alternately arranged at intervals along the first direction and are alternately arranged at intervals along the second direction; and
forming a plurality of semiconductor regions of a second conductivity type in the semiconductor layer by ion implantation of second conductivity type impurities into the semiconductor layer through the plurality of first opening portions and the plurality of second opening portions, wherein
the semiconductor device includes a semiconductor substrate that includes a first semiconductor layer of p-type, a drift layer disposed below the first semiconductor layer, and a second semiconductor layer of n-type disposed below the drift layer,
the drift layer includes a first semiconductor region of the first conductivity type, a plurality of second semiconductor regions of the second conductivity type, and a plurality of third semiconductor regions of the second conductivity type,
the plurality of second semiconductor regions and the plurality of third semiconductor regions are distributed in the first semiconductor region,
each of the plurality of second semiconductor regions has a shape elongated in the first direction,
each of the plurality of third semiconductor regions has a shape elongated in the second direction,
the plurality of second semiconductor regions and the plurality of third semiconductor regions are alternately arranged at intervals along the first direction, and are alternately arranged at intervals along the second direction,
in the plurality of semiconductor regions, a plurality of regions formed by the ion implantation through the plurality of first opening portions becomes the plurality of second semiconductor regions, respectively,
in the plurality of semiconductor regions, a plurality of regions formed by the ion implantation through the plurality of second opening portions becomes the plurality of third semiconductor regions, respectively, and
in the semiconductor layer, a region that remains after the plurality of semiconductor regions is formed becomes the first semiconductor region.
